(19) United States
(12) Patent Application Publication
(10) Pub. No.: US 2025/0175744 A1
(43) Pub. Date: May 29, 2025

(54) MEMS transducer having at least one metal layer and one oxide layer

(71) Applicant: USOUND GMBH, Graz (AT)

(72) Inventors: Andrea Rusconi Clerici Beltrami, Wien (AT); Ferruccio Bottoni, Graz (AT); Christian Novotny, Wien (AT); Samu Bence Horváth, Wien (AT)

(21) Appl. No.: 18/962,616

(22) Filed: Nov. 27, 2024

(30) Foreign Application Priority Data
Nov. 29, 2023 (DE) 10 2023 133 448.4

(51) Int. Cl. H04R 17/02; H10N 30/50

(52) U.S. Cl. CPC H04R 17/02; H10N 30/50; H04R 2201/003

(57) ABSTRACT

In one aspect, a MEMS transducer, in particular a MEMS sound transducer unit, preferably for generating and/or detecting sound waves in the audible wavelength spectrum and/or in the ultrasonic range, includes a carrier and at least one piezoelectric element. The piezoelectric element(s) is arranged on the carrier and is deflectable in the direction of a stroke axis, with the piezoelectric element(s) having at least one piezoelectric layer and at least one carrier layer, wherein, by means of the at least one piezoelectric layer, electrical signals and deflections of the piezoelectric element can be converted from one into the other. The carrier layer includes at least one metal layer and at least one oxide layer.

### CROSS-REFERENCE TO RELATED APPLICATIONS

The present application is based upon and claims the right of priority to German Patent Application No. 10 2023 133 448.4, filed Nov. 29, 2023, the disclosure of which is hereby incorporated by reference herein in its entirety for all purposes.

### FIELD OF THE INVENTION

The present subject matter relates to a MEMS transducer, in particular a MEMS sound transducer unit, preferably for generating and/or detecting sound waves in the audible wavelength spectrum and/or in the ultrasonic range. The MEMS transducer has a carrier and at least one piezoelectric element, which is arranged on the carrier and is deflectable in the direction of a stroke axis and has at least one piezoelectric layer and at least one carrier layer, wherein, by means of the at least one piezoelectric layer, electrical signals and deflections of the piezoelectric element can be converted from one into the other.

### BACKGROUND OF THE INVENTION

A need currently exists in the art fore a powerful MEMS transducer.

### SUMMARY OF THE INVENTION

In various aspects, the present subject matter is directed to a MEMS transducer, a use of a carrier layer for a MEMS transducer, and a method for producing the MEMS transducer having the features described and claimed herein. Advantageous or preferred embodiments are in each case the subject matter of the description and/or claims.

In one aspect, the present subject matter relates to a MEMS transducer, preferably a MEMS sound transducer, in particular for generating and/or detecting sound waves in the audible wavelength spectrum and/or in the ultrasonic range. The MEMS transducer can be operated as a loudspeaker and/or as a microphone and thus as a MEMS sound transducer.

The MEMS sound transducer includes a carrier.

Moreover, the MEMS transducer includes at least one piezoelectric element, which is arranged on the carrier and is deflectable in the direction of a stroke axis.

In addition, the at least one piezoelectric element has at least one piezoelectric layer and at least one carrier layer, wherein, by means of the piezoelectric layers, electrical signals and deflections of the piezoelectric element can be converted from one into the other.

Moreover, the carrier layer includes at least one metal layer and at least one oxide layer.

It is advantageous when the piezoelectric layers are made of scandium-aluminum nitride. Such piezoelectric layers are highly robust, which is due, in particular, to the scandium content, which can preferably be between 30% and 70%. It can be particularly advantageous when the scandium content is 30%, 40%, or 50%.

It is advantageous when the at least one piezoelectric layer is arranged below or above the carrier layer in the direction of the stroke axis.

It is also advantageous when two piezoelectric layers are arranged below or above the carrier layer in the direction of the stroke axis.

Furthermore, it is advantageous when the metal layer is an aluminum layer. Additionally or alternatively, it is advantageous when the oxide layer is a silicon oxide layer. By means of these materials, the carrier layer can be formed using known production methods, for example by means of methods that are used in semiconductor technology. Consequently, the carrier layer can be produced in large quantities and/or at very low cost. Moreover, the aluminum layer and the silicon oxide layer have a comparable modulus of elasticity in the range of 70 GPa auf. As a result, the two layers have similar or nearly identical deflection properties.

The at least one oxide layer and/or at least one metal layer also have the advantage that they are thermally stable up to high temperatures, for example up to 1200° C.-1400° C. Consequently, the piezoelectric layers and/or electrode layers can be applied using methods from semiconductor technology, for example a CMOS-compatible method. For example, the piezoelectric layers and/or the electrode layers can be applied using a CVD (chemical vapor deposition) method.

Furthermore, it is advantageous when the carrier layer includes multiple metal layers and multiple oxide layers. The metal layers and the oxide layers can also be arranged alternatingly one above the other and/or stacked. As a result, a sandwich-like construction of the carrier layer is formed. Such a carrier layer is therefore a stack including multiple layers, preferably including at least one metal layer and at least one, in particular at least two, oxide layer(s). The carrier layer can also be a structural layer.

It is advantageous when the uppermost or the lowermost layer in the direction of the stroke axis is an oxide layer. In the layered construction of the carrier layer by means of the at least one metal layer and at least two oxide layers, the uppermost layer and/or the lowermost layer in the direction of the stroke axis are/is an oxide layer. This has the advantage that the oxide layer, in particular the silicon oxide layer, has the highest thermal stability. The piezoelectric layer and/or the electrode layer are/is applied, in particular at higher temperatures, onto these oxide layers, which form both the uppermost layer and the lowermost layer. The oxide layer does not change at the higher temperatures.

The oxide layer, in particular the silicon oxide layer, can also be easily machined. For example, this layer can be chemically-mechanically polished. Such a method is known as CMP (chemical mechanical polishing, or chemical mechanical planarization). The oxide layer, in particular the silicon oxide layer, can thereby be made very flat and/or planar.

It is advantageous when the piezoelectric element has a length in the longitudinal direction thereof, in particular from the carrier to a free end of the piezoelectric element, between 0.5 mm and 2 mm.

It is advantageous when the at least one piezoelectric layer is arranged on only one side of the carrier layer in the direction of the stroke axis.

Additionally or alternatively, it is advantageous when the at least one piezoelectric layer is on one side of the carrier layer in the direction of the stroke axis and the opposite side is free of the at least one piezoelectric layer.

It is advantageous when the at least one piezoelectric layer is arranged, in the direction of the stroke axis, only and/or exclusively between the carrier and the carrier layer. Due to the described arrangement of the at least one piezoelectric layer on only one side of the carrier layer, the piezoelectric element can be produced easily and in an uncomplicated manner.

It is advantageous when the at least one piezoelectric element includes multiple, in particular between two and six, preferably four, piezoelectric layers.

An advantage results when the at least one piezoelectric element includes at least one electrode layer. By means of the at least one electrode layer, the electrical signals can be exchanged, which electrical signals result in the deflection of the piezoelectric element and/or are formed when the piezoelectric element is deflected.

It is advantageous when the at least one piezoelectric element includes at least one insulation layer.

It is advantageous when the at least one piezoelectric element is formed from the multiple piezoelectric layers and the electrode layers in a sandwich-like manner.

An advantage results when the MEMS sound transducer includes a coupling element, by means of which the at least one piezoelectric element can be coupled to a diaphragm.

An improvement results when the piezoelectric element and the coupling element are coupled together by means of at least one spring element, which at least one spring element is preferably arranged between the carrier layer and the coupling element in the longitudinal direction of the piezoelectric element.

It is advantageous when the spring element is formed, preferably exclusively, by the carrier layer. As a result, the spring element can be easily formed.

It is advantageous when the spring element is made of a polymer, in particular of polyamide. Additionally or alternatively, the spring element has the mechanical properties of the polymer.

It is useful when the piezoelectric element and the coupling element have the same layered construction.

An improvement results when the carrier layer is between 5 μm and 100 μm thick. Preferably, the carrier layer has a thickness of less than 100 μm.

Moreover, it is advantageous when the carrier layer has a modulus of elasticity between 40 GPa and 300 GPa.

Due to the aforementioned mechanical properties of the at least one carrier layer, the deflections can be enlarged and/or the piezoelectric element can be shortened while the size of the deflection at least remains the same or the deflection enlarges.

Moreover, it is advantageous when the piezoelectric element includes at least one compensation layer. This compensation layer can be arranged on the carrier layer and/or on the at least one piezoelectric layer. The carrier layer can be arranged between the compensation layer and the at least one piezoelectric layer. By means of the compensation layer, the neutral plane can be shifted along the stroke axis.

It is also advantageous when the at least one piezoelectric layer is arranged, in the direction of the stroke axis, between the carrier and the carrier layer.

The present subject matter also relates to a use of the carrier layer for the MEMS transducer. The MEMS transducer has at least one feature of the preceding description and/or the following description. Additionally or alternatively, the carrier layer has at least one feature of the preceding description and/or the following description. In particular, the carrier layer can include at least one metal layer, in particular an aluminum layer, and/or at least one oxide layer, in particular a silicon oxide layer, and optionally at least one further feature associated therewith.

The present subject matter also relates to a method for producing a MEMS transducer, preferably a MEMS sound transducer, in particular for generating and/or detecting sound waves in the audible wavelength spectrum and/or in the ultrasonic range. The method for producing the MEMS transducer can be carried out such that the MEMS transducer is formed having at least one feature of the preceding description and/or the following description.

In the method, at least one piezoelectric element is formed on a carrier, which piezoelectric element has at least two piezoelectric layers and at least one carrier layer coupled thereto.

Moreover, in the method, the carrier layer is arranged between at least two piezoelectric layers. As a result, a symmetrical construction of the piezoelectric element, in particular in the direction of the stroke axis, can be formed. Consequently, advantageous deflection properties can be obtained.

It is also useful when an oxide layer, in particular a silicon oxide layer, is machined by means of chemical mechanical polishing. As a result, the oxide layer is made flat and/or planar. The at least one piezoelectric layer and/or at least one electrode layer is then applied onto this flat and/or planar oxide layer.

It is advantageous when the piezoelectric layers are formed on the carrier layer by means of semiconductor production methods.

It is also advantageous when the piezoelectric layers are deposited on the carrier layer. The piezoelectric layer, at least the first piezoelectric layer, can also be deposited on the oxide layer. All subsequent piezoelectric layers are then deposited one after the other.

It is also advantageous when the piezoelectric layers are formed on the carrier layer and/or the carrier layer is formed by means of chemical vapor deposition. As a result, well understood methods are used for forming the piezoelectric layers and/or the electrode layers. In addition, such methods can be particularly easily carried out.

The metal layer, the oxide layer, the electrode layer, and/or the piezoelectric layer can be formed, and/or, in particular on existing layers, arranged using CMOS-compatible methods.

Furthermore, it is useful when, after the piezoelectric layers and/or the carrier layer have/has been formed, at least one region is removed, in particular by means of etching. The piezoelectric layers and/or the carrier layer can be built up on each other by means of the method steps described here.

It is useful when the piezoelectric layers are made of scandium-aluminum nitride.

It is also advantageous when the at least one piezoelectric element is formed having multiple, in particular between two and six, in particular four, piezoelectric layers. By using multiple piezoelectric layers, the power of the piezoelectric element can be increased.

Moreover, it is advantageous when the same number of piezoelectric layers are arranged above and below the carrier layer in the direction of the stroke axis.

For example, it is advantageous when in each case two piezoelectric layers are arranged above and below the carrier layer in the direction of the stroke axis, such that the piezoelectric element includes four piezoelectric layers overall.

It is useful when the at least one piezoelectric element is formed of the multiple piezoelectric layers and at least one electrode layer in a sandwich-like manner.

The multiple piezoelectric layers and multiple electrode layers can be arranged alternatingly one above the other.

Moreover, it is advantageous when at least one insulation layer is included in the build-up of the at least one piezoelectric element.

It is useful when the carrier layer made of the polymer is arranged on a side of the piezoelectric layer facing away from the carrier.

An improvement results when the carrier layer made of the polymer is provided on the at least one piezoelectric layer after the piezoelectric layer and/or a coupling element have/has been formed, and/or after the carrier, the piezoelectric layer, and/or the coupling element have/has been reworked, in particular separated from one another, in particular by means of etching.

It is useful when the piezoelectric element and the coupling element are built up together in a layered construction, this preferably being carried out on the carrier.

It is advantageous when, once the piezoelectric element and the coupling element have been built up in a layered construction, these are separated from one another, at least in some sections, in particular by means of etching.

Moreover, a method can be carried out in order to provide the MEMS transducer according to the preceding description and/or the following description.

### BRIEF DESCRIPTION OF THE FIGURES

Further advantages of the invention are described in the following exemplary embodiments, wherein:

FIG. 1 shows a schematic sectional view of a MEMS transducer having a piezoelectric element including two piezoelectric layers and at least one carrier layer,

FIG. 2 shows a schematic sectional view of the piezoelectric element including two piezoelectric layers and at least one carrier layer,

FIG. 3 shows a schematic sectional view of the piezoelectric element having in each case two piezoelectric layers above and below the carrier layer in the direction of the stroke axis, and

FIG. 4 shows a schematic sectional view of the carrier layer including metal layers and oxide layers.

### DETAILED DESCRIPTION

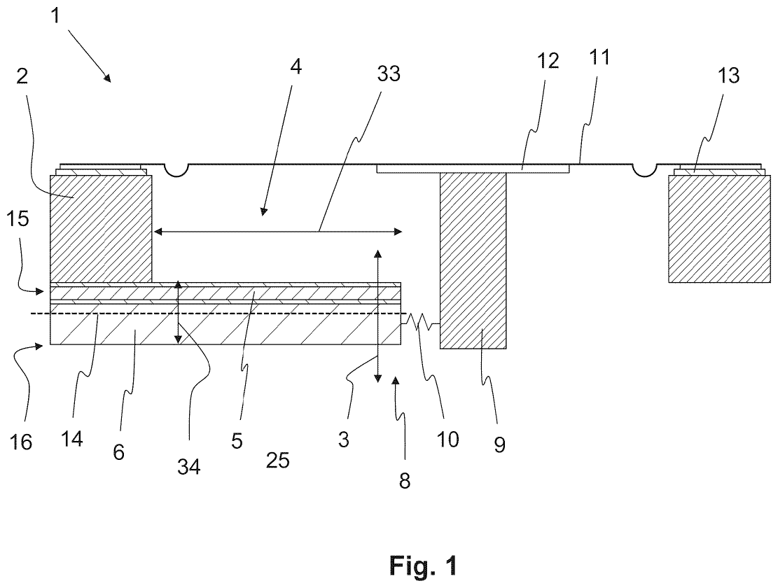

FIG. 1 shows a schematic sectional view of a MEMS transducer 1. The MEMS transducer 1 can also be a MEMS sound transducer. By means of the MEMS sound transducer, for example, sound waves in the audible wavelength spectrum can be generated, enabling the MEMS sound transducer to be operated as a MEMS loudspeaker. By means of the MEMS sound transducer, additionally or alternatively, sound waves in the audible wavelength spectrum can be detected, allowing the MEMS sound transducer to be operated as a MEMS microphone. Furthermore, the MEMS sound transducer can be arranged, for example, in a smartphone, in order to allow, for example, telephoning or listening to music. The MEMS sound transducer can also be arranged, for example, in headphones. By means of the MEMS transducer 1, in addition, pressures can be generated and/or detected.

A further area of application of the MEMS sound transducer can also be that of generating and/or detecting sound waves in the ultrasonic range. The MEMS sound transducer can be arranged, for example, in an ultrasonic sensor, for example, a distance sensor.

The MEMS transducer 1 includes a carrier 2, which can form a framework of the MEMS transducer 1. The carrier 2 can include, for example, a semiconductor substrate, which can be produced in an etching process. The carrier 2 can be made, for example, of silicon and/or have the shape of a wafer. Two carriers 2 are shown in the present view of FIG. 1. The carrier 2 can be in the form of a frame, however, such that the two elements of the carrier 2 shown in FIG. 1 can be contiguous in this sectional view shown. For example, the carrier 2 can be rectangular as seen in a top view. The top view can be oriented, for example, in the direction of a stroke axis 3, which is explained in the following description. The top view can be, for example, parallel to the stroke axis 3. For example, at least one piezoelectric element 4 can at least partly face an interior of the carrier 2 when the carrier 2 is in the form, for example, of a frame.

Moreover, at least one piezoelectric element 4 is arranged on the carrier 2. The at least one piezoelectric element 4 can also be coupled to the carrier 2. The at least one piezoelectric element 4 can be deflected along the stroke axis 3 shown in FIG. 1. In this process, the at least one piezoelectric element 4 can convert electrical signals into deflections, so that the MEMS transducer 1 is operated as a loudspeaker and the sound waves can be generated. Additionally or alternatively, by means of the at least one piezoelectric element 4, deflections can also be converted into electrical signals, so that the MEMS sound transducer 1 is operated as a microphone and the sound waves can be detected. By means of the deflections, pressures can also be generated, however. Additionally or alternatively, pressures can also be detected, since pressures induce a deflection of the at least one piezoelectric element 4.

The at least one piezoelectric element 4 has a free end 8, which can deflect along the stroke axis 3.

The piezoelectric element 4 also includes at least one piezoelectric layer 5, 25, 35, 36. The at least one piezoelectric layer 5, 25, 35, 36 is made of a piezoelectric material. The at least one piezoelectric layer 5, 25, 35, 36 can convert electrical signals into deflections and/or deflections into electrical signals.

The at least one piezoelectric layer 5, 25, 35, 36 can also be made of scandium-aluminum nitride (ScAlN).

In addition, the piezoelectric element 4 includes at least one carrier layer 6. This is coupled to the at least one piezoelectric layer 5, 25, 35, 36. At least one piezoelectric layer 5, 25, 35, 36 is arranged between the carrier 2 and the at least one carrier layer 6. By means of the at least one carrier layer 6, the at least one piezoelectric layer 5, 25, 35, 36 can be stabilized. Furthermore, by means of the at least one carrier layer 6, the at least one piezoelectric layer 5, 25, 35, 36 can be prevented from breaking during deflection. The at least one carrier layer 6 can also act as a carrier layer for the at least one piezoelectric layer 5, 25, 35, 36. A first piezoelectric layer 5 is shown in this exemplary embodiment from FIG. 1.

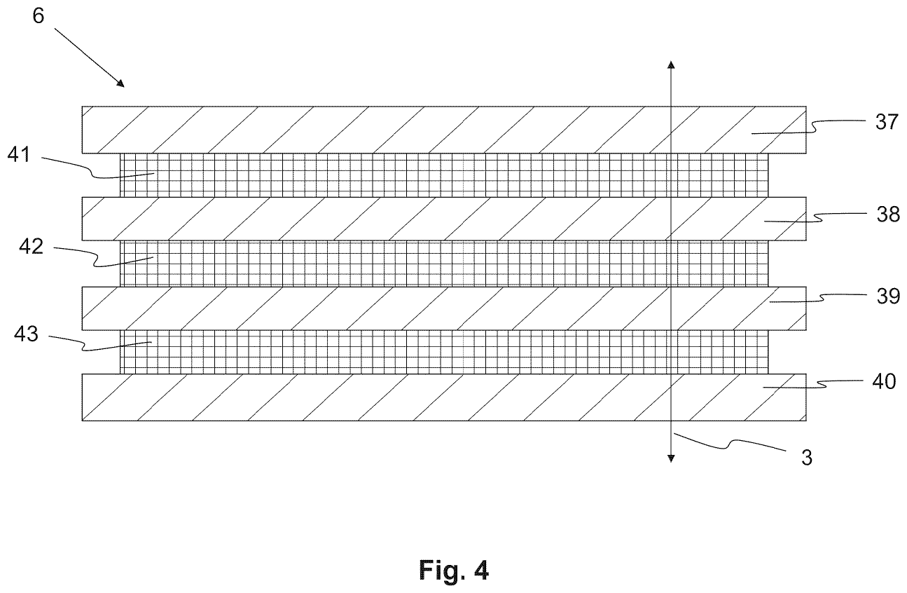

The carrier layer 6 also includes at least one metal layer 41-43 and at least one oxide layer 37-40, as shown in greater detail in FIG. 4.

The at least one piezoelectric layer 5, 25, 35, 36 is arranged on only one side of the carrier layer 6. According to the present exemplary embodiment, the at least one piezoelectric layer 5, 25, 35, 36 is arranged between the carrier 2 and the carrier layer 6 in the direction of the stroke axis 3. Alternatively, the at least one piezoelectric layer 5, 25, 35, 36 can also be arranged, however, on the side of the carrier layer 6 facing away from the carrier 2. Consequently, in this alternative exemplary embodiment, the carrier layer 6 is arranged between the carrier 2 and the at least one piezoelectric layer 5, 25, 35, 36 in the direction of the stroke axis 3.

According to the present exemplary embodiment, the MEMS transducer 1 includes a coupling element 9, by means of which the at least one piezoelectric element 4 can be coupled to a diaphragm 11 (shown in FIG. 1) of the MEMS transducer 1. By means of the coupling element 9, the deflections of the piezoelectric element 4 can be transmitted onto the diaphragm 11 when the sound waves are generated by means of the diaphragm 11 (e.g., when the MEMS transducer 1 is a MEMS sound transducer). Additionally or alternatively, the deflections of the diaphragm 11 can also be transmitted onto the piezoelectric element 4 when the sound waves are detected by means of the diaphragm 11 (e.g., when the MEMS transducer 1 is a MEMS sound transducer).

According to the present exemplary embodiment, the piezoelectric element 4 is coupled to the coupling element 9 by means of a spring element 10. The spring element 10 can be made, for example, of a polymer. The spring element therefore has a flexibility.

It is advantageous when a coupling plate 12 is arranged between the coupling element 9 and the diaphragm 11, as shown in FIG. 1. By means of the coupling plate 12, a planar transmission of the deflections between the coupling element 9 and the diaphragm 11 can be achieved. According to the present exemplary embodiment, a diaphragm frame 13 is also shown in FIG. 1, by means of which the diaphragm 11 can be arranged on the carrier 2.

Moreover, the at least one piezoelectric element 4 has a length 33. The length 33 is defined in this case from the carrier 2 to the free end 8 of the at least one piezoelectric element 4. The length 33 can be between 0.5 mm and 2 mm. Due to the carrier layer 6, the piezoelectric element 4 can have this length 33, while large deflections along the stroke axis 3 are possible. The deflection of the at least one piezoelectric element 4, in particular at the free end 8, can be at least 3%, preferably at least 10%.

A thickness 34 of the at least one piezoelectric element 4 can be between 2 μm and 50 μm. The thickness 34 is oriented parallel to the stroke axis 3 and/or perpendicularly to the layers of the at least one piezoelectric element 4 (cf. FIG. 4).

Moreover, the at least one piezoelectric element 4 can have at least one recess (not shown in FIG. 1). The at least one recess can extend at least partially between a top side 15 and a bottom side 16 of the at least one piezoelectric element 4. The at least one recess can extend from the top side 15 and/or from the bottom side 16 in the direction of the respective oppositely positioned top side or bottom side 15, 16. By means of these recesses, tensions in the piezoelectric element 4, or in the at least one piezoelectric layer 5, 25, 35, 36, and/or in the at least one carrier layer 6, can be reduced.

The top side 15 faces the diaphragm 11 in this embodiment shown in FIG. 1, whilethe bottom side 16 faces away from the diaphragm 11. The terms top side 15 and bottom side 16 are also used to define the terms above and below. The terms top side 15 and bottom side 16 as well as above and below relate to the direction of the stroke axis 3.

A neutral plane 14 is also shown in FIG. 1. The neutral plane 14 is a term from the science of the strength of materials and is also referred to as a neutral axis, or neutral line. The neutral axis, or neutral plane 14, or the neutral line, is the plane, or line, in the piezoelectric element 4 where the tensile stress and the compressive stress cancel each other out and, therefore, no tension occurs at such axis/plane/line. By comparison, either tensile stresses or compressive stresses act above and below this neutral axis/plane/line. The tensile stress or the compressive stress naturally occurs in this case only when the piezoelectric element 4 deflects. If the piezoelectric element 4 is deflected, for example, upward, i.e., in the direction away from the carrier 2, compressive stress acts in an upper region of the piezoelectric element 4 and tensile stress acts in a lower region of the piezoelectric element 4. By comparison, when the piezoelectric element 4 deflects downward, i.e., towards the carrier 2, the compressive stress and the tensile stress are reversed. Neither tensile stress nor compressive stress acts in the neutral plane 14, or in the neutral layer, which plane 14, or layer, is arranged between the top side 15 and the bottom side 16 of the piezoelectric element 4. By means of the first piezoelectric layer 5 and a second piezoelectric layer 25, the position of the neutral axis, or the neutral plane 14 (or layer), or the neutral line, is adapted vertically, or in the direction of the stroke axis 3, above and below the carrier layer 6 in the direction of the stroke axis 3. Since the piezoelectric layers 5, 25, 35, 36 are also designed similarly to one another, i.e., are made of the same material, for example AlScN, and/or have an identical thickness 34, the neutral plane 14 is arranged centrally in the piezoelectric element 4 and/or in the carrier layer 6.

The MEMS transducer 1 shown here has only one piezoelectric element 4. Alternatively, the MEMS transducer 1 can also have multiple piezoelectric elements 4, which are coupled to one or more diaphragm(s) 11.

Features that have already been described with reference to the at least one preceding figure are not explained once more for the sake of simplicity. Furthermore, features can also be first described in this figure or in at least one of the following figures. Moreover, identical reference characters are used for identical features for the sake of simplicity. In addition, all features may not be shown again in the following figures and/or provided with a reference character for the sake of clarity. Features shown in one or more of the preceding figures can also be present in this figure or in one or more of the following figures, however. Furthermore, features can also be shown and/or provided with a reference character first in this feature or in one or more of the following features for the sake of clarity. Nevertheless, features that are first shown in one or more of the following figures can also be already present in this figure or in a preceding figure.

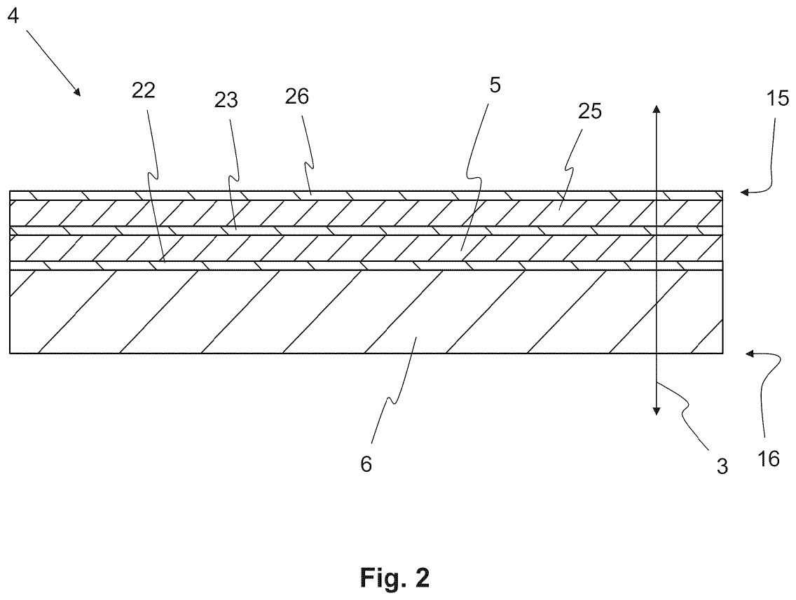

FIG. 2 shows a more detailed schematic sectional view of the piezoelectric element 4. For the sake of clarity, the more precise construction of the piezoelectric element 4 is explained with reference to FIG. 2.

Here, at least two piezoelectric layers 5, 25 are shown in FIG. 2, which two piezoelectric layers 5, 25 are arranged on one side of the carrier layer 6.

Furthermore, multiple electrode layers 22, 23, 26 are shown in FIG. 2. Specifically, three electrode layers 22, 23, 26 are shown in the exemplary embodiment of FIG. 2. By means of the electrode layers 22, 23, 26, the two piezoelectric layers 5, 25 can be supplied with an electrical signal, so that the piezoelectric layers deflect, or the electrical signal can be conducted away when the piezoelectric layers themselves deflect.

As is apparent in FIG. 2, the piezoelectric layers 5, 25 and the electrode layers 22, 23, 26 are arranged alternatingly one above the other. One piezoelectric layer 5, 25 is arranged in each case between two electrode layers 22, 23, 26.

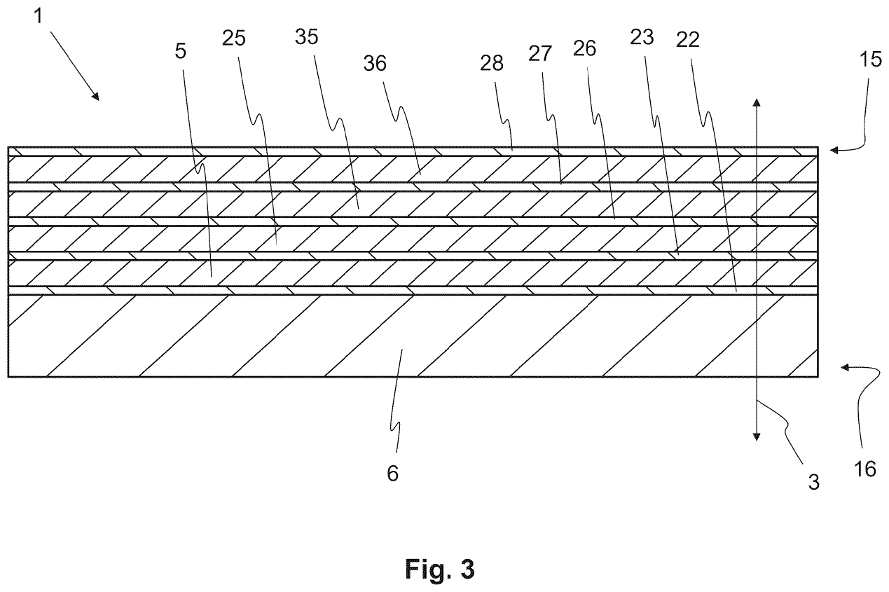

FIG. 3 shows an exemplary embodiment of the piezoelectric element 4, which includes a carrier layer 6 and four piezoelectric layers 5, 25, 35, 36. Moreover, five electrode layers 22, 23, 26, 27, 28 are shown in FIG. 3. The piezoelectric layers 5, 25, 35, 36 and the electrode layers 22, 23, 26, 27, 28 are again arranged alternatingly one above the other. The piezoelectric layers 5, 25, 35, 36 and the electrode layers 22, 23, 26, 27, 28 are arranged, in particular only, on one side of the carrier layer 6.

FIG. 4 shows an exemplary embodiment of the carrier layer 6 in a sectional view. As is apparent in FIG. 4, the carrier layer 6 is formed of further layers 37-43. The carrier layer 6 includes at least one oxide layer 37-40 and at least one metal layer 41-43. By means of the stroke axis 3, it should be clear what is meant by above and below with reference to FIG. 4.

The at least one metal layer 41-43 can preferably be made of aluminum. Additionally or alternatively, the at least one oxide layer 37-40 can be made of silicon oxide. By means of these materials, the carrier layer 6 and the at least one piezoelectric layer 5, 25, 35, 36 arranged thereon can be formed using known production methods, for example by means of methods that are used in semiconductor technology, for example CMOS-compatible methods.

The at least one oxide layer 37-40 and/or at least one metal layer 41-43 also have the advantage that they are thermally stable up to high temperatures, for example up to 1200° C.-1400° C. Consequently, the piezoelectric layers 5, 25, 35, 36 and/or the electrode layers 22, 23, 26-29 can be applied using methods from semiconductor technology, for example CMOS-compatible methods. For example, the piezoelectric layers 5, 25, 35, 36 and/or the electrode layers 22, 23, 26-29 can be applied using a CVD (chemical vapor deposition) method.

In the exemplary embodiment of FIG. 4, the carrier layer 6 includes four oxide layers 37-40 and three metal layers 41-43, which, as is apparent in FIG. 4, are advantageously arranged alternatingly one above the other in the direction of the stroke axis 3. One oxide layer 37, 40 is also arranged above and below in the direction of the stroke axis 3. The at least one piezoelectric layer 5, 25, 35, 36 can be arranged on the first or the fourth oxide layer 37, 40 shown in FIG. 4. It is advantageous when the at least one piezoelectric layer 5, 25, 35, 36 is arranged on an oxide layer 37-40, since the oxide layer 37-40 is temperature-stable and easily machined. On the side on which there is no piezoelectric layer 5, 25, 35, 36, the carrier layer 6 can end with a metal layer 41-43 or an oxide layer 37-40.

Moreover, the oxide layer 37-40 can be followed first by an electrode layer 22, 23, 26-29, which is then followed in turn by the piezoelectric layer 5, 25, 35, 36. This is the case, however, only when an electrode for the piezoelectric layer 5, 25, 35, 36 is also formed as an electrode layer 22, 23, 26-29. The electrode for the piezoelectric layer 5, 25, 35, 36 can also be arranged on a side face of the piezoelectric layer 5, 25, 35, 36. The piezoelectric layer 5, 25, 35, 36 could then directly adjoin the first or the fourth oxide layer 37, 40.

Moreover, an electrode layer 22, 23, 26-29 can also extend partially between the piezoelectric layer 5, 25, 35, 36 and the adjacent oxide layer 3740

As is shown in FIG. 4, the oxide layers 37-40 project laterally beyond the metal layers 41-43. Additionally or alternatively, some, in particular all, oxide layers 37-40 and metal layers 41-43 can be flush or congruent.

As is apparent in FIG. 4, the carrier layer 6 includes four oxide layers 37-40 and three metal layers 41-43. Alternatively, the carrier layer 6 can also include only two or one oxide layer(s) 37-40 and one metal layer 41-43.

Furthermore, alternatively, the carrier layer 6 can also include multiple oxide layers 37-40, for example eleven, and multiple metal layers 41-43, for example ten.

It is advantageous when the carrier layer 6 has an oxide layer 37-40 above and below in the direction of the stroke axis 3. Furthermore, the uppermost and the lowermost layers of the layered construction of the carrier layer 6 can be an oxide layer 37-40. Additionally, one metal layer 41-43 is arranged in each case between two oxide layers 37-40. Therefore, the number of oxide layers 37-40 is one greater than the number of metal layers 41-43.

The oxide layers 37-40 have the advantage that they can be easily further machined. For example, the oxide layers 37-40 can be machined by means of chemical mechanical polishing. As a result, a flat and/or planar surface is formed on the oxide layer 37-40, on which surface the at least one piezoelectric layer 5, 25, 35, 36 and/or the electrode layer 22, 23, 26-29 are/is then arranged. It is therefore advantageous when the uppermost and the lowermost layers of the carrier layer are an oxide layer 37-40.

There are four oxide layers 37-40 and three metal layers 41-43 in the embodiment shown in FIG. 4 in order to obtain a thickness 34 of the piezoelectric element 4 of approximately 7 μm, which is advantageous for the deflection and for the performance of the piezoelectric element 4. The number of oxide layers 37-40 and metal layers 41-43 and, therefore, the thickness 34 of the piezoelectric element 4, also depend on the length 33 of the piezoelectric element 4.

### List of reference characters

1 MEMS transducer
2 carrier
3 stroke axis
4 piezoelectric element
5 first piezoelectric layer
6 carrier layer
8 free end
9 coupling element
10 spring element
11 diaphragm
12 first coupling plate
13 diaphragm frame
14 neutral plane
15 top side
16 bottom side
22 first electrode layer
23 second electrode layer
25 second piezoelectric layer
26 third electrode layer
27 fourth electrode layer
28 fifth electrode layer
33 length
34 thickness
35 third piezoelectric layer
36 fourth piezoelectric layer
37 first oxide layer
38 second oxide layer
39 third oxide layer
40 fourth oxide layer
41 first metal layer
42 second metal layer
43 third metal layer

1-20. (canceled)

21. A MEMS transducer, comprising:
a carrier;
at least one piezoelectric element arranged on the carrier and deflectable in a direction of a stroke axis, the at least one piezoelectric element having at least one piezoelectric layer and at least one carrier layer, wherein the at least one piezoelectric layer is configured to convert electrical signals and deflections of the at least one piezoelectric element from one into the other,
wherein the carrier layer includes at least one metal layer and at least one oxide layer.

22. The MEMS transducer of claim 21, wherein the at least one piezoelectric layer is made of scandium-aluminum nitride, wherein a scandium content is between 30% and 70%.

23. The MEMS transducer of claim 21, wherein the at least one metal layer is an aluminum layer, and/or the at least one oxide layer is a silicon oxide layer.

24. The MEMS transducer of claim 21, wherein the at least one metal layer comprises multiple metal layers and the at least one oxide layer comprises multiple oxide layers, the metal and oxide layers being arranged alternatingly one above the other and/or stacked.

25. The MEMS transducer of claim 21, wherein the at least one piezoelectric layer is arranged on the at least one oxide layer.

26. The MEMS transducer of claim 21, wherein the at least one piezoelectric layer is arranged below or above the carrier layer in the direction of the stroke axis.

27. The MEMS transducer of claim 21, wherein:
the at least one piezoelectric layer is arranged on only one side of the carrier layer in the direction of the stroke axis (3); and/or
the at least one piezoelectric layer is on one side of the carrier layer in the direction of the stroke axis and an opposite side of the carrier layer is free of the at least one piezoelectric layer.

28. The MEMS transducer of claim 21, wherein the at least one piezoelectric layer is arranged, in the direction of the stroke axis, only exclusively between the carrier and the carrier layer.

29. The MEMS transducer of claim 21, wherein the at least one piezoelectric element has a length in a longitudinal direction thereof from the carrier to a free end of the at least one piezoelectric element, the length ranging between 0.5 mm and 2 mm.

30. The MEMS transducer of claim 21, wherein:
the at least one piezoelectric layer includes between two and six piezoelectric layers; and/or
the at least one piezoelectric element includes at least one electrode layer; and/or
the at least one piezoelectric element includes at least one insulation layer.

31. The MEMS transducer of claim 21, further comprising a coupling element that couples the at least one piezoelectric element to a diaphragm.

32. The MEMS transducer of claim 31, wherein the at least one piezoelectric element and the coupling element are coupled together by at least one spring element, wherein the at least one spring element is arranged between the carrier layer and the coupling element in a longitudinal direction of the at least one piezoelectric element.

33. The MEMS transducer of claim 32, wherein the spring element is formed by the carrier layer and/or by a polymer.

34. The use of a carrier layer for a MEMS transducer, wherein the MEMS transducer and/or the carrier layer is designed according to claim 21.

35. A method for producing a MEMS transducer that includes a carrier and at least one piezoelectric element deflectable in a direction of a stroke axis, the at least one piezoelectric element having at least two piezoelectric layers and at least one carrier layer, wherein the at least two piezoelectric layers are configured to convert electrical signals and deflections of the at least one piezoelectric element from one into the other, the method comprising:
forming the at least one carrier layer as at least one metal layer and at least one oxide layer; and
arranging the at least one piezoelectric element on the carrier.

36. The method of claim 35, wherein the at least one oxide layer is at least one silicon oxide layer, further comprising machining the at least one silicon oxide layer via chemical mechanical polishing.

37. The method of claim 35, further comprising forming the at least two piezoelectric layers on the at least one carrier layer using at least one semiconductor production method.

38. The method of claim 35, further comprising depositing the at least two piezoelectric layers on the at least one oxide layer of the carrier layer.

39. The method of claim 35, further comprising forming the at least two piezoelectric layers on the carrier layer and/or forming the carrier layer using a chemical vapor deposition.

40. The method of claim 35, further comprising removing at least one region of the at least one piezoelectric element after the at least two piezoelectric layers and/or the carrier layer (6) have/has been formed.
